(19) United States
(12) Patent Application Publication
(10) Pub. No.: US 2010/0117127 A1
(43) Pub. Date: May 13, 2010

(54) SEMICONDUCTOR STORAGE DEVICE AND METHOD OF MANUFACTURING THE SAME

(75) Inventor: Yoshinori KUMURA, Albany, CA (US)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/563,068

(22) Filed: Sep. 18, 2009

(30) Foreign Application Priority Data
Nov. 12, 2008 (JP) 2008-289357

(51) Int. Cl. H01L 27/108; H01L 21/02

(52) U.S. Cl. 257/295; 438/3; 257/E27.084; 257/E21.008

(57) ABSTRACT

A semiconductor storage device includes a memory cell having a ferroelectric capacitor and a cell transistor connected in parallel. The memory cell includes: a first conductive layer provided above a substrate; a ferroelectric layer formed on a top surface of the first conductive layer; a second conductive layer formed on a top surface of the ferroelectric layer; and a stopper layer formed in the same layer as the ferroelectric layer. A selection ratio of the stopper layer under CMP is higher than that of the ferroelectric layer under CMP.

### CROSS-REFERENCE TO RELATED APPLICATIONS

This application is based upon and claims the benefit of priority from the prior Japanese Patent Application No. 2008-289357, filed on Nov. 12, 2008, the entire contents of which are incorporated herein by reference.

### BACKGROUND OF THE INVENTION

### 1. Field of the Invention

The present invention relates to a semiconductor storage device such as ferroelectric memory (FeRAM) and a method of manufacturing the same.

2. Description of the Related Art

Storage devices (ferroelectric memory: FeRAM) using ferroelectric capacitors as storage media have been developed and put into practical use (see, for example, Japanese Patent Laid-Open No. 2002-25247). The ferroelectric memory has significant characteristics. For example, stored data will not be lost even after the power is turned off due to its non-volatility, high-speed write and read operations are available because of the capability of rapid inversion of spontaneous polarization when a film thickness of the ferroelectric capacitor is small enough, and so on. In addition, the ferroelectric memory is suitable for large-capacity memory because a memory cell of 1 bit can be configured by one transistor and one ferroelectric capacitor.

With the conventional techniques, it is difficult to deposit a uniform film thickness of not more than 100 nm over the wafer surface due to the morphology of the ferroelectric film (which functions as a ferroelectric capacitor). As such, the ferroelectric film is planarized by Chemical Mechanical Polishing (CMP) and processed to a thickness of not more than 100 nm. The thickness uniformity of the ferroelectric film after the deposition is generally on the order of ±5%.

However, when the CMP process is performed on the ferroelectric film, the thickness uniformity of the ferroelectric film is determined by the thickness uniformity of deposition thereof and thickness uniformity of CMP thereof in the wafer added thereto. Accordingly, after the CMP process, the thickness uniformity of the ferroelectric film within the wafer surface can be up to on the order of ±10%. That is, the CMP degrades the thickness uniformity of the ferroelectric film in the wafer surface. Such degradation in thickness uniformity of the ferroelectric film causes variations in the electric field applied to a ferroelectric material.

In the ferroelectric memory, the polarization of the ferroelectric film is inverted to switch between “1” and “0” as information. Such polarization inversion is caused by an electric field that is equal to or greater than the coercive electric field applied to the ferroelectric capacitor. Consequently, any variations in the electric field applied to the ferroelectric material lead to non-uniform polarization inversion characteristics. That is, this will result in variations in memory characteristics.

### SUMMARY OF THE INVENTION

One aspect of the present invention provides a semiconductor storage device comprising: a memory cell having a ferroelectric capacitor and a cell transistor connected in parallel, the memory cell comprising: a first conductive layer provided above a substrate; a ferroelectric layer formed on a top surface of the first conductive layer; a second conductive layer formed on a top surface of the ferroelectric layer; and a stopper layer formed in the same layer as the ferroelectric layer, a selection ratio of the stopper layer under CMP being higher than that of the ferroelectric layer under CMP.

In addition, another aspect of the present invention provides a method of manufacturing a semiconductor storage device, the method comprising: depositing a first conductive layer above a substrate; depositing a stopper layer in a certain pattern on a top surface of the first conductive layer; depositing a ferroelectric layer so as to cover the first conductive layer and the stopper layer; planarizing the ferroelectric layer by chemical mechanical polishing so that a top surface of the ferroelectric layer is aligned with a top surface of the stopper layer; and depositing a second conductive layer on the respective top surfaces of the stopper layer and the planarized ferroelectric layer, a selection ratio of the stopper layer under CMP being higher than that of the ferroelectric layer under CMP.

### BRIEF DESCRIPTION OF THE DRAWINGS

FIG. 1 is a block diagram illustrating a configuration of a semiconductor storage device 100 according to a first embodiment of the present invention;

FIG. 2A schematically illustrates a standby state of the semiconductor storage device 100 of the first embodiment;

FIG. 2B schematically illustrates a standby state of the semiconductor storage device 100 of the first embodiment;

FIG. 3A schematically illustrates an operation state of the semiconductor storage device 100 of the first embodiment;

FIG. 3B schematically illustrates an operation state of the semiconductor storage device 100 of the first embodiment;

FIG. 4 is a cross-sectional view of a memory cell array la according to the first embodiment;

FIG. 5 illustrates a first manufacturing process of the capacitor layer 30 according to the first embodiment;

FIG. 6 illustrates the first manufacturing process of the capacitor layer 30 of the first embodiment;

FIG. 7 illustrates the first manufacturing process of the capacitor layer 30 of the first embodiment;

FIG. 8 illustrates the first manufacturing process of the capacitor layer 30 of the first embodiment;

FIG. 9 illustrates the first manufacturing process of the capacitor layer 30 of the first embodiment;

FIG. 10 illustrates the first manufacturing process of the capacitor layer 30 of the first embodiment;

FIG. 11 illustrates the first manufacturing process of the capacitor layer 30 of the first embodiment;

FIG. 12 illustrates a second manufacturing process of the capacitor layer 30 according to the first embodiment;

FIG. 13 is a diagram for describing advantages of the second manufacturing process according to the first embodiment;

FIG. 14 is a cross-sectional view of a memory cell array 1aA according to a second embodiment;

FIG. 15 is a diagram for describing advantages of the second embodiment;

FIG. 16 is a cross-sectional view of a memory cell array 1aB according to a third embodiment; and

FIG. 17 is a top plan view illustrating the ferroelectric layers 32B and the stopper layers 33B according to the third embodiment.

### DETAILED DESCRIPTION OF THE EMBODIMENTS

Embodiments of a semiconductor storage device according to the present invention and a method of manufacturing the same will be described below with reference to the accompanying drawings.

### First Embodiment

(Circuit Configuration of Semiconductor Storage Device 100 in First Embodiment)

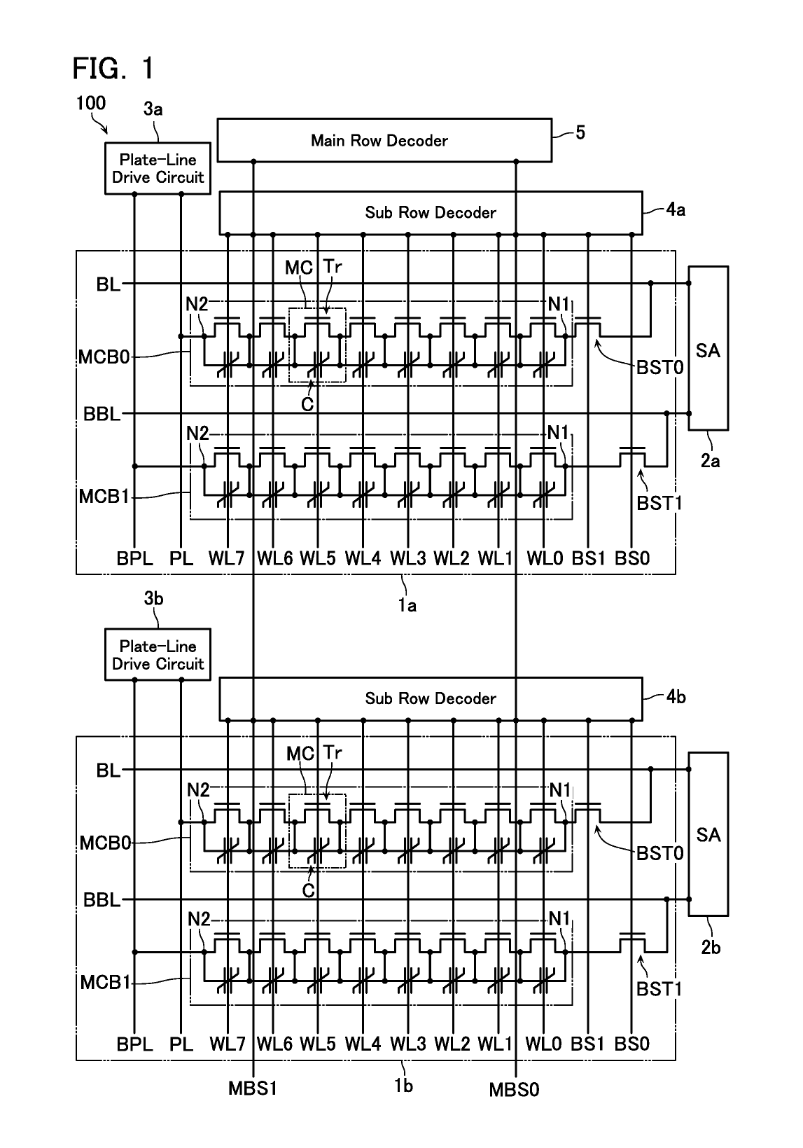

Referring first to FIG. 1, a circuit configuration of a semiconductor storage device 100 according to a first embodiment of the present invention will be described below. FIG. 1 is a block diagram illustrating a configuration of the semiconductor storage device 100 of the first embodiment. As illustrated in FIG. 1, the semiconductor storage device 100 includes: memory cell arrays 1a, 1b for storing data; sense amplifier circuits 2a, 2b for sensing and amplifying read data; plate-line drive circuits 3a, 3b; sub row decoder circuits 4a, 4b; and a main row decoder circuit 5.

Each of the memory cell arrays 1a and 1b includes memory cells MC, each of which includes a ferroelectric capacitor C and a cell transistor Tr. In each of the memory cells MC, the ferroelectric capacitor C and the cell transistor Tr are connected in parallel. In the example illustrated in FIG. 1, there are eight memory cells MC so configured that are connected in series to provide respective cell blocks MCB0 and MCB1. That is, the respective cell blocks MCB0 and MCB1 are included in TC parallel unit serial connection type ferroelectric memory (FeRAM). FIG. 1 illustrates two cell blocks MCB0 and MCB1 connected to a respective pair of bit lines BL and BBL.

The cell blocks MCB0 and MCB1 have one ends N1 connected to the bit lines BL and BBL via block selection transistors BST0 and BST1, and the other ends N2 connected to plate lines PL and BPL. In the respective cell blocks MCB0 and MCB1, the gates of the cell transistors Tr are connected to respective word lines WL0 to WL7.

The bit lines BL and BBL are connected to the sense amplifier circuit 2a (or 2b). In addition, the plate lines PL and BPL are connected to the plate-line drive circuit 3a (or 3b), and the word lines WL0 to WL7 are connected to the sub row decoder circuit 4a (or 4b). Furthermore, the sub row decoder circuits 4a, 4b and the main row decoder circuit 5 are connected to each other by main block selection lines MBS0 and MBS1.

The plate-line drive circuit 3a (or 3b) has a function for selectively driving the plate lines PL and BPL. The sub row decoder circuit 4a (or 4b) has a function for selectively driving the word lines WL0 to WL7. The main row decoder circuit 5 has a function for selectively driving the sub row decoder circuits 4a, 4b using control signals via the main block selection lines MES0 and MBS1.

(Operation of Semiconductor Storage Device 100 in First Embodiment)

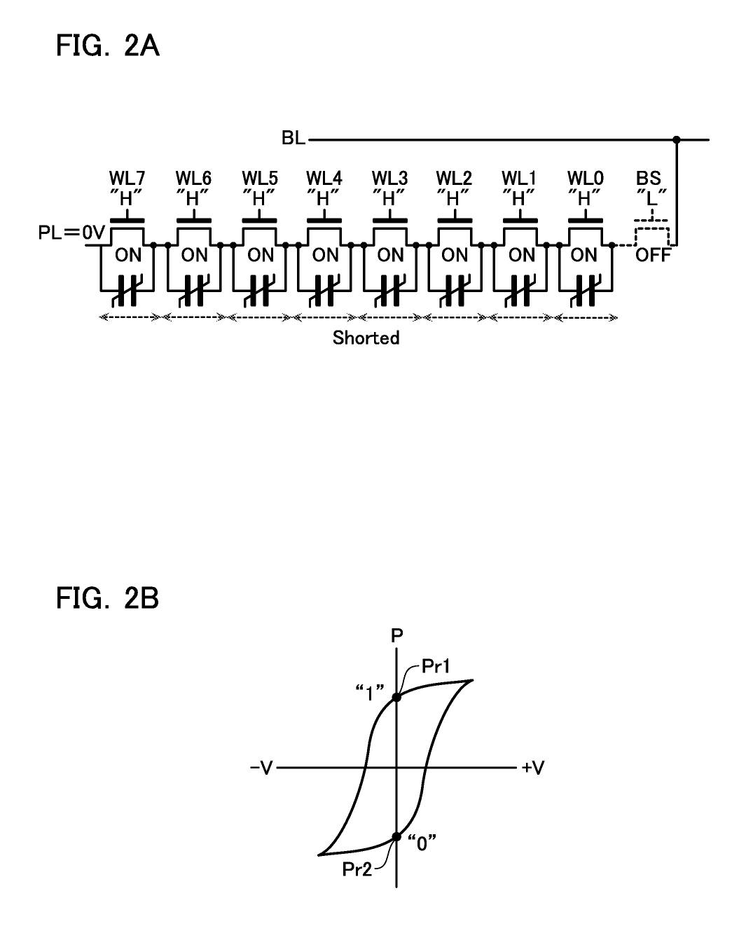

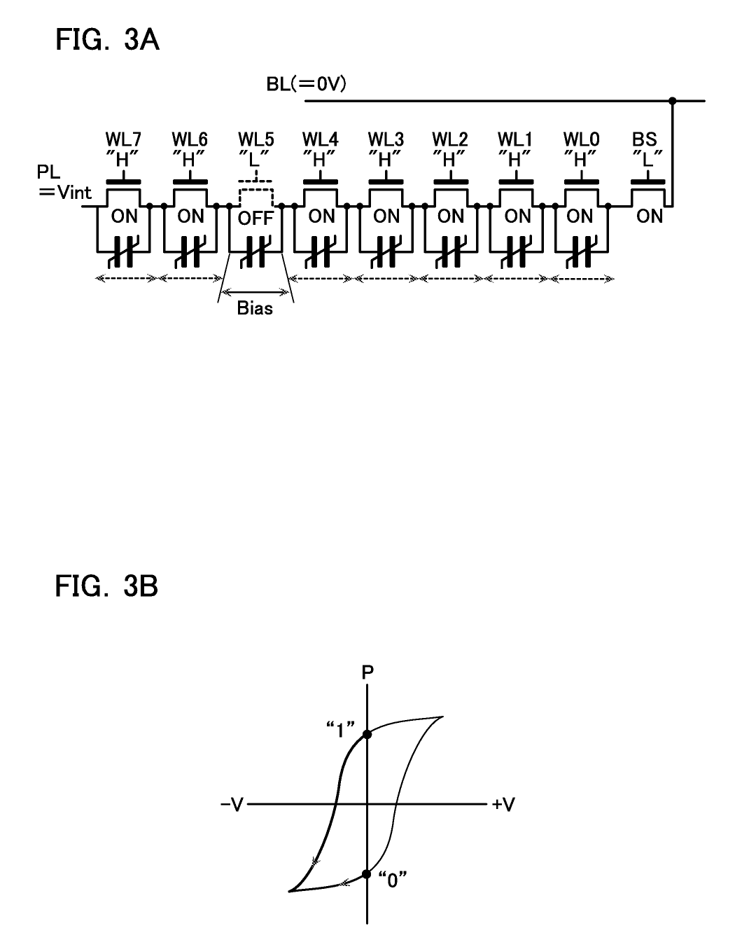

Referring now to FIGS. 2A, 2B, 3A, and 3B, an operation of the semiconductor storage device 100 according to the first embodiment will be described below. Here, as an example, the following description will be made on an operation of the cell block MCB0 in the memory cell array 1a. FIGS. 2A and 2B schematically illustrate a standby state of the semiconductor storage device 100 of the first embodiment; and FIGS. 3A and 3B schematically illustrate an operation state of the semiconductor storage device 100 of the first embodiment.

As illustrated in FIG. 2A, during a standby state, the sub row decoder circuit 4a drives the word lines WL0 to WL7 to an “H (High)” state. Because of this drive operation, the respective cell transistors Tr are set in an on state. In addition, the sub row decoder circuit 4a drives a block selection line BS to an “L (Low)” state. As a result, the block selection transistor BST0 is set in an off state. In addition, the plate-line drive circuit 3a sets the plate line PL at 0V. Through these operations, the ferroelectric capacitors C of the memory cells MC are set in a short-circuit.

In this case, in the memory cells MC (FeRAM), either a memory cell storing data “1” or a memory cell storing data “0” should necessarily experience inversion of spontaneous polarization when one word line WL is set to “L” for reading and voltage is applied to the ferroelectric capacitors. Accordingly, a rewrite operation is required after the read operation for inverting again the inverted spontaneous polarization based on the read data. As illustrated in FIG. 2B, for example, spontaneous polarization Pr1 and Pr2 in the hysteresis characteristics of the ferroelectric capacitors represent the states of stored data “1” and “0”, respectively.

Then, as illustrated in FIG. 3A, during an operation state, the sub row decoder circuit 4a drives the block selection line BS to an “H (High)” state. As a result, the block selection transistor BST0 is set in an on state. The bit line BL is precharged to a certain potential (0V) by a precharge circuit (not illustrated), and then set in a floating state. Then, the plate-line drive circuit 3a boosts the plate line PL to Vint. Thereafter, the sub row decoder circuit 4a drives a selected word line (in this case, WL5) to an “L (Low)” state. As a result, only the cell transistor Tr to which the word line WL5 is connected is set in an off state, after which data is read from the ferroelectric capacitors C connected in parallel.

As can be seen from the above-mentioned operation, voltage caused in the bit line BL varies depending upon the amounts of remaining polarization for “1” data and “0” data as illustrated in FIG. 3B. The sense amplifier circuit 2a reads the difference between the amounts of signals.

(Structure of Memory Cell Array 1a in Semiconductor Storage Device 100 in First Embodiment)

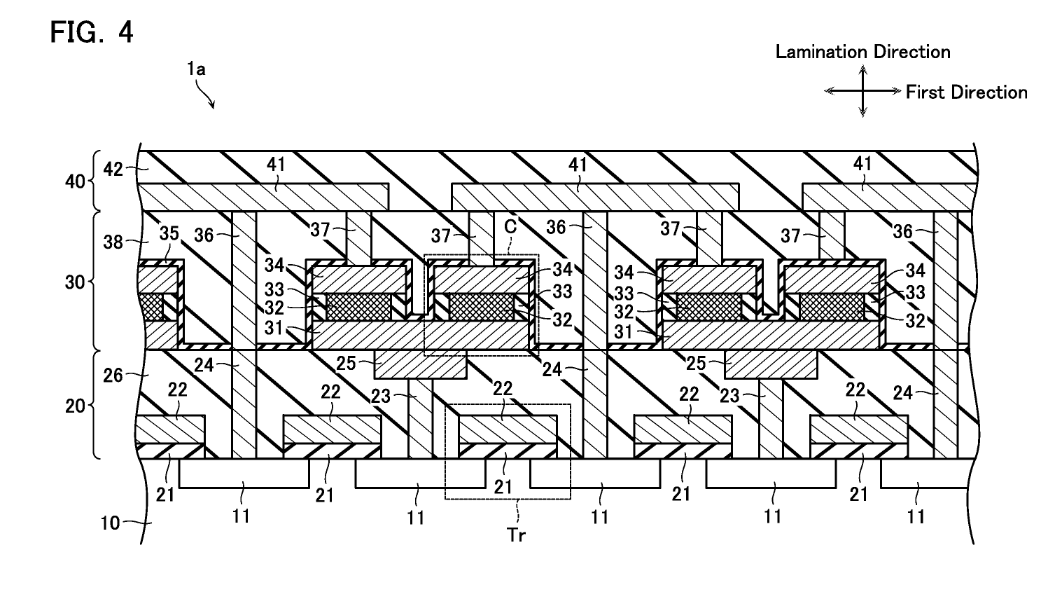

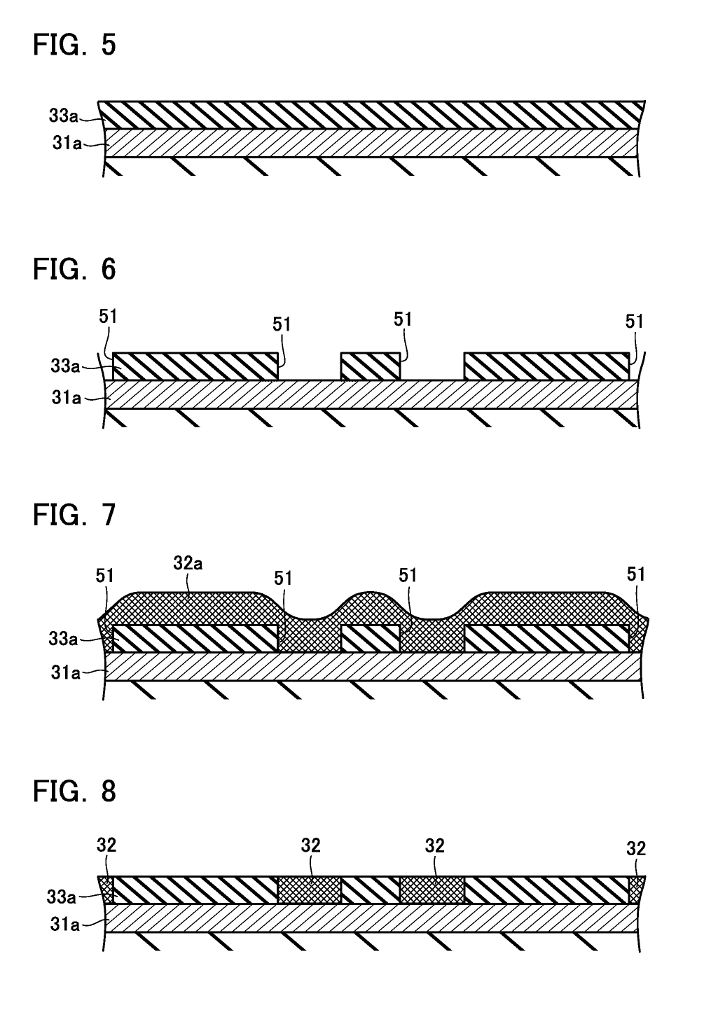

Referring now to FIGS. 4 and 5, a structure of the memory cell array 1a in the semiconductor storage device 100 according to the first embodiment will be described below. FIG. 4 is a cross-sectional view of the memory cell array 1a. FIG. 5 is a schematic top plan view illustrating a part of FIG. 4.

As illustrated in FIG. 4, the memory cell array 1a has a transistor layer 20, a capacitor layer 30, and a wiring layer 40 that are sequentially laminated on a substrate 10. The transistor layer 20 has the function of the above-mentioned cell transistors Tr. The capacitor layer 30 has the function of the ferroelectric capacitors C. The transistor layer 20 and the capacitor layer 30 also have the function of the above-mentioned memory cells MC.

As illustrated in FIG. 4, the substrate 10 has source/drain layers 11 provided at a certain pitch on its top surface. In addition to this, although not illustrated in the figure, the substrate 10 has an STI (Shallow Trench Isolation) region for device isolation within the substrate 10. The source/drain layers 11 are included in the sources/drains of the respective cell transistors Tr.

As illustrated in FIG. 4, the transistor layer 20 has gate insulation layers 21, gate conductive layers 22, first and second contact plug layers 23, 24, contact layers 25, and interlayer insulation layers 26.

The gate insulation layers 21 and the gate conductive layers 22 are sequentially laminated on the surface of the substrate 10. The gate insulation layers 21 and the gate conductive layers 22 are formed across the corresponding source/drain layers 11 at a certain pitch in a first direction orthogonal to a lamination direction. The first and second contact plug layers 23, 24 are formed to extend in the lamination direction from the top surfaces of the source/drain layers 11. The first and second contact plug layers 23, 24 are alternately formed at a certain pitch in the first direction. The contact layers 25 are formed on the top surfaces of the first contact plug layers 23. The interlayer insulation layers 26 are formed up to the top surfaces of the contact layers 25 (the second contact plug layers 24) so as to fill up the above-mentioned layers 21 to 25.

The gate insulation layers 21 are composed of silicon oxide (SiO₂). The gate conductive layers 22 are composed of polysilicon. The first and second contact plug layers 23, 24 are composed of polycrystalline silicon doped with tungsten (W). The contact layers 25 are composed of, e.g., tungsten. The interlayer insulation layers 26 are composed of any one of BPSG (Boron Phosphorous Silicate Glass) and P-TEOS (Plasma-Tetra Ethoxy Silane).

In the above-mentioned configuration of the transistor layer 20, the gate insulation layers 21 and the gate conductive layers 22 function as cell transistors Tr together with the source/drain layers 11. In addition, the gate conductive layers 22 function as the control gate electrodes of the cell transistors Tr.

As illustrated in FIG. 4, the capacitor layer 30 has first conductive layers 31, ferroelectric layers 32, stopper layers 33, second conductive layers 34, a protection layer 35, third and fourth contact plug layers 36, 37, and interlayer insulation layers 38.

The first conductive layers 31 are formed on the top surfaces of the respective contact layers 25. The ferroelectric layers 32 are formed on the top surfaces of the respective first conductive layers 31 in such a way that two ferroelectric layers 32 are formed on the first conductive layer 31 with a certain distance in the first direction from each other. The stopper layers 33 are formed on the top surfaces of the first conductive layers 31, i.e., they are formed in the same layer as the ferroelectric layers 32. The stopper layers 33 are formed in contact with the side surfaces of the ferroelectric layers 32. The second conductive layers are formed on the respective top surfaces of the ferroelectric layers 32 and the stopper layers 33.

The protection layer 35 is formed to cover the side surfaces of the first conductive layers 31, the side surfaces of the stopper layers 33, and both the side and top surfaces of the second conductive layers 34. The third contact plug layers 36 are formed to extend in the lamination direction from the top surfaces of the second contact plug layers 24 so as to penetrate the protection layer 35. The fourth contact plug layers 37 are formed to extend in the lamination direction from the top surfaces of the second conductive layers 34 so as to penetrate the protection layer 35. The interlayer insulation layers 38 are formed up to the respective top surfaces of the third and fourth contact plug layers 36 and 37 so as to fill up the above-mentioned layers 31 to 37.

The first conductive layers 31 and the second conductive layers 34 are configured to include any one of Pt, Ir, IrO₂, SRO, Ru, and RuO₂. The ferroelectric layers 32 include any one of lead zirconate titanate (PZT), strontium bismuth tantalate (SET), and bismuth ferrite (BFO).

The stopper layers 33 are configured to have a higher selection ratio under chemical mechanical polishing as compared with that of the ferroelectric layers 32. The stopper layers 33 are composed of, e.g., either alumina (Al₂O₃) or silicon nitride (SiN). The stopper layers 33 may also be composed of lamination of alumina and a noble metal film (such as Ir or Ot). The stopper layers 33 function as stoppers when planarizing and forming ferroelectric layers 32 by CMP, which will be described in detail below.

The protection layer 35 functions as a so-called hydrogen diffusion barrier layer. The protection layer 35 is composed of anyone of Al₂O₃, SiN, and TiO₂. The third and fourth contact plug layers 36, 37 are composed of polycrystalline silicon doped with tungsten (W). The interlayer insulation layers 38 are composed of any one of P-TEOS, O₃-TEOS, SGO, and Low-k layers (such as SiOF or SiOC).

In the above-mentioned configuration of the capacitor layer 30, the first conductive layers 31, the ferroelectric layers 32, and the second conductive layers 34 function as ferroelectric capacitors C.

As illustrated in FIG. 4, the wiring layer 40 has first wiring layers 41 and an interlayer insulation layer 42. Note that the wiring layer 40 has additional layers above the first wiring layers 41 that function as bit lines BL, BBL, word lines WL0 to WL7, and so on, although not illustrated in the figure. Each first wiring layer 41 is formed to connect the top surface of a third contact plug layer 36 to the top surfaces of a pair of fourth contact plug layers 37.

The first wiring layers 41 are composed of aluminum (Al) or copper (Cu). The interlayer insulation layer 42 is composed of any one of P-TEOS, O₃-TEOS, SGO, and Low-k layers (such as SiOF or SiOC).

(First Manufacturing Process of Capacitor Layer 30 in First Embodiment)

Referring now to FIGS. 5 to 11, a first manufacturing process of the capacitor layer 30 according to the first embodiment will be described below. FIGS. 5 to 11 illustrate the first manufacturing process of the capacitor layer 30 according to the first embodiment.

Firstly, as illustrated in FIG. 5, Pt (or any one of Ir, IrO₂, SRO, Ru, and RuO₂) and alumina (Al₂O₃) (or silicon nitride (SiN)) are sequentially laminated to form layers 31a and 33a. In addition, the layer 33a may be formed by laminating alumina and a noble metal film (such as Ir or Ot). Note that the layer 31a will provide first conductive layers 31 through a subsequent step. The layer 33a will provide stopper layers 33 through a subsequent step.

Then, as illustrated in FIG. 6, etching is performed to form trenches 51 in a certain pattern so as to penetrate the layer 33a.

Then, as illustrated in FIG. 7, Metal Organic Chemical Vapor Deposition (MOCVD) is performed to deposit PZT (or either SBT or BFO) so as to fill up the trenches 51 and to cover the layers 31a and 33a. As a result, a layer 32a is formed. Note that the layer 32a will provide ferroelectric layers 32 through a subsequent step.

Then, as illustrated in FIG. 8, CMP is performed to planarize the layer 32a. Through this step, the layer 32a provides ferroelectric layers 32. In this step, the layers 33a are configured to have a higher selection ratio under chemical mechanical polishing as compared with that of the ferroelectric layers 32 (the layer 32a). Thus, the CMP is performed so that the top surfaces of the ferroelectric layers 32 are aligned with the top surfaces of the layers 33a.

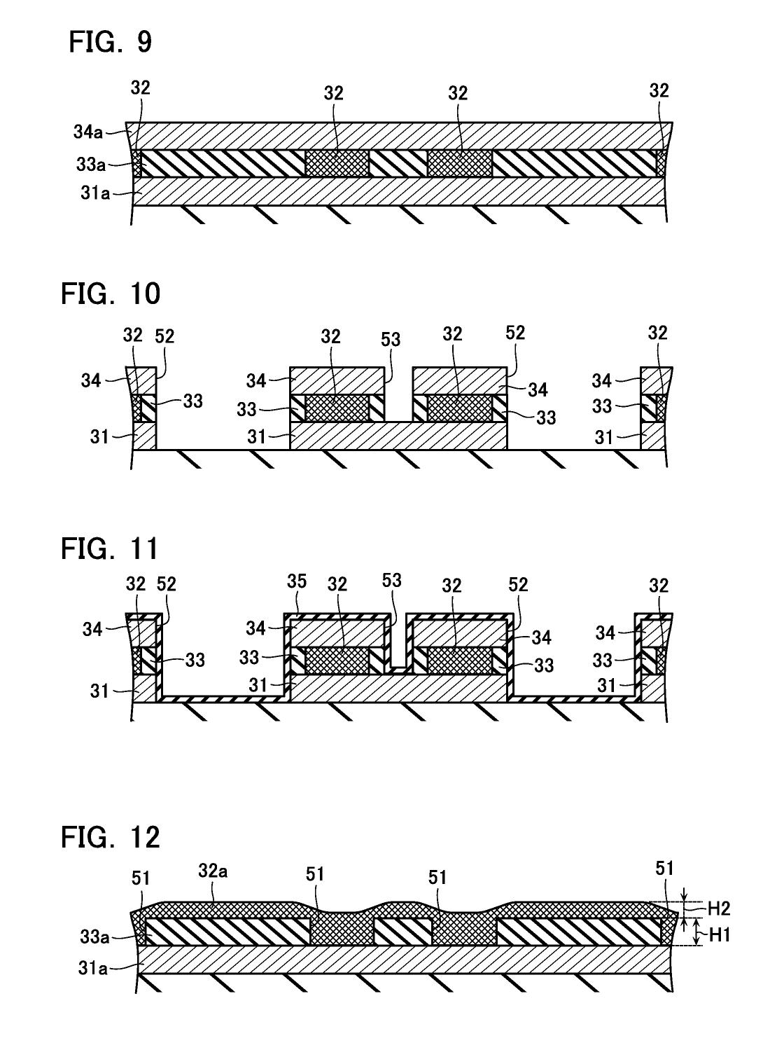

Then, as illustrated in FIG. 9, Pt (or any one of Ir, IrO₂, SRO, Ru, and RuO₂) is deposited on the respective top surfaces of the ferroelectric layers 32 and the layers 33a, thereby forming a layer 34a. Note that the layer 34a will provide second conductive layers 34 through a subsequent step.

Then, as illustrated in FIG. 10, trenches 52 are formed in a certain pattern so as to penetrate the layers 31a, 33a, and 34a. In addition, trenches 53 are formed in a certain pattern so as to penetrate the layers 33a and 34a. In this step, the layer 31a provides first conductive layers 31. The layers 33a provide stopper layers 33. The layer 34a provides second conductive layers 34.

Then, as illustrated in FIG. 11, Al₂O₃ (or either SiN or TiO₂) is deposited to form a protection layer 35.

Subsequent to FIG. 11, interlayer insulation layers 38 and third and fourth contact plug layers 36, 37 are formed. Through this process, the capacitor layer 30 is manufactured as illustrated in FIG. 4.

(Second Manufacturing Process of Capacitor Layer 30 in First Embodiment)

Referring now to FIG. 12, a second manufacturing process of the capacitor layer 30 according to the first embodiment will be described below. FIG. 12 illustrates the second manufacturing process of the capacitor layer 30 according to the first embodiment.

Firstly, as in the first manufacturing process, the steps of FIGS. 5 and 6 are performed. Then, the layer 32a is deposited as illustrated in FIG. 12. In the process of FIG. 12, the layer 32a (which later provides ferroelectric layers 32) is formed in such a way that a growing rate of the layer 32a from the top and side surfaces of the layers 33a (which later provides stopper layers 33) will be slower than that from the top surface of the layer 31a (which later provides first conductive layers 31). For example, as illustrated in FIG. 12, the layer 32a is formed with a height H1 from the top surface of the layer 31a and another height H2 (H2<H1) from the top surfaces of the layers 33a.

For example, if the layer 31a is composed of a material having a heat conductivity higher than that of the layers 33a, then the surface temperature of the layer 31a may be higher than that of the layers 33a. This allows the layer 32a to be grown at a faster growing rate at the layer 31a having a higher surface temperature. In addition, the layer 31a may be composed of a material having a nucleation density higher than that of the layers 33a.

Subsequently, the same steps are performed as illustrated in FIGS. 8 to FIG. 11 in relation to the first manufacturing method. Through this process, the capacitor layer 30 is manufactured as illustrated in FIG. 4.

(Advantages of First Embodiment)

Advantages of the semiconductor storage device 100 according to the first embodiment will now be described below. As can be seen from the first embodiment described above, the capacitor layer 30 has the stopper layers 33 in the same layer as the ferroelectric layers 32. The stopper layers 33 have a selection ratio under chemical mechanical polishing that is higher than that of the ferroelectric layers 32. Due to the existence of the stopper layers 33, the top surfaces of the ferroelectric layers 32 are planarized with high accuracy when performing chemical mechanical polishing. That is, the semiconductor storage device 100 may suppress variations in the memory characteristics.

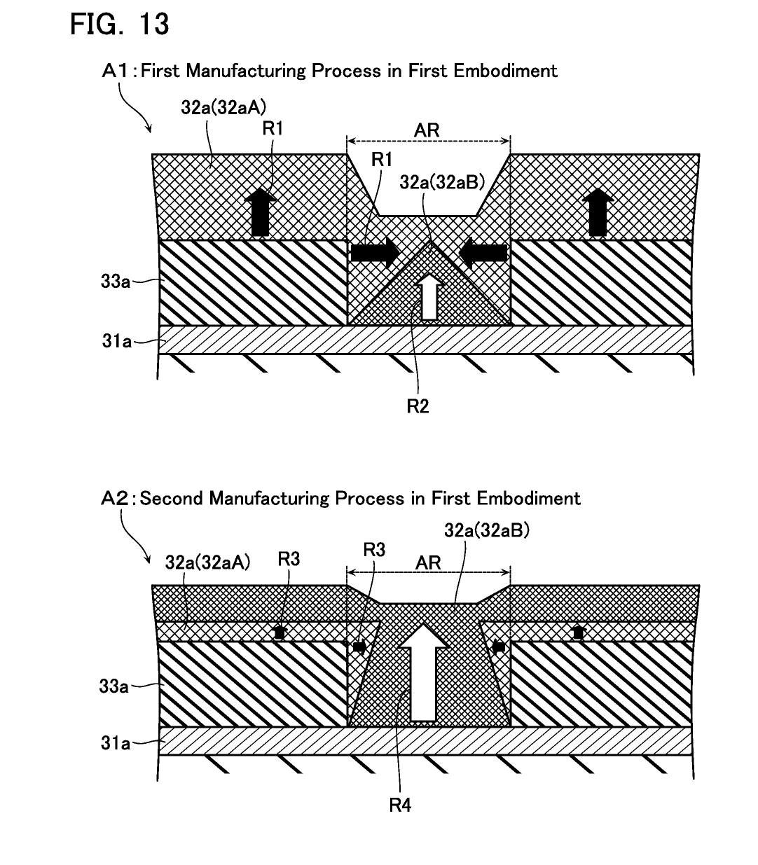

Referring now to FIG. 13, advantages of the second manufacturing process of the first embodiment will be described, compared with the first manufacturing process of the first embodiment. Generally, the layer 32a (32aA) formed from the layers 33a (which later provides stopper layers 33) exhibits worse ferroelectric characteristics than those of the layer 32a (32aB) formed from the layer 31a (which later provides first conductive layers 31). In this case, according to the first manufacturing process A1, the layer 32a (32aA) is grown from the top and side surfaces of the layers 33a at a growing rate R1 that is equal to a growing rate R2 of the layer 32a (32aB) at which it is grown from the top surface of the layer 31a. In contrast, according to the second manufacturing process A2, the layer 32a (32aA) is grown from the top and side surfaces of the layers 33a at a growing rate R3 that is slower than a growing rate R4 of the layer 32a (32aB) at which it is grown from the top surface of the layer 31a.

As such, the second manufacturing process A2 allows the layer 32aA to bear a smaller ratio to the layer 32aB than in the first manufacturing process A1 in an area AR that will eventually provide ferroelectric layers 32. That is, the second manufacturing process may suppress degradation in characteristics of the layer 32a (the ferroelectric layers 32) as compared with the first manufacturing process.

### Second Embodiment

(Structure of Semiconductor Storage Device in Second Embodiment)

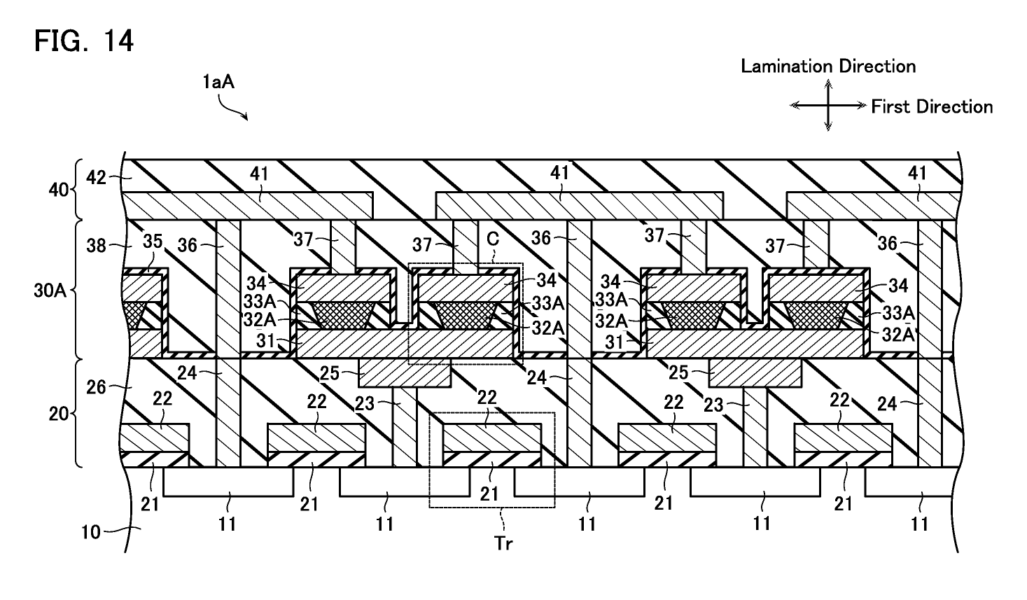

Referring now to FIG. 14, a structure of a semiconductor storage device according to a second embodiment will be described below. FIG. 14 is a cross-sectional view of a memory cell array 1aA according to the second embodiment. Note that the same reference numerals represent the same components as the first embodiment, and description thereof will be omitted in the second embodiment.

As illustrated in FIG. 14, the memory cell array 1aA according to the second embodiment has a capacitor layer 30A different from the first embodiment. The capacitor layer 30A has ferroelectric layers 32A and stopper layers 33A that are different from the first embodiment.

The ferroelectric layer 32A has a side surface facing the stopper layer 33A, the side surface being formed in a forward-inclined shape with respect to the substrate 10 (generally trapezoidal shape with the bottom surface having a smaller length than that of the top surface). The stopper layer 33A has a side surface facing ferroelectric layer 32A, the side surface being formed in a backward-inclined shape with respect to the substrate 10. Note that in the second embodiment, the ferroelectric layers 32A are formed with the second manufacturing process of the first embodiment.

(Advantages of Second Embodiment)

Advantages of the semiconductor storage device according to the second embodiment will be described below. As in the first embodiment, the stopper layers 33A are formed in the same layer as the ferroelectric layers 32A. Accordingly, the semiconductor storage device of the second embodiment has the same advantages as the first embodiment.

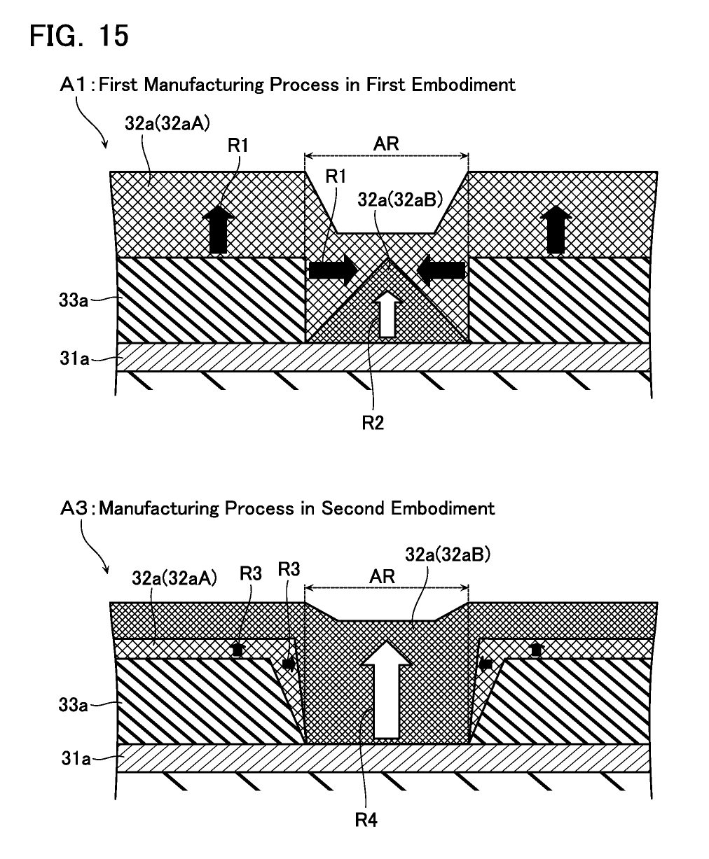

Referring now to FIG. 15, advantages of a manufacturing process A3 of the second embodiment are described, compared with the first manufacturing process A1 of the first embodiment. According to the first manufacturing process A1 of the first embodiment, a layer 32aA with poor ferroelectric characteristics is formed in an area AR that will eventually provide ferroelectric layers 32, as illustrated in FIG. 15. In contrast, in the manufacturing process A3 of the second embodiment, the side surfaces, facing the ferroelectric layers 32A, of the stopper layers 33A are formed in a backward-inclined shape. Thus, as can be seen from FIG. 15, the manufacturing process A3 of the second embodiment allows only the layer 32aB with good ferroelectric characteristics to be formed in the area AR that will eventually provide the ferroelectric layers 32A. That is, the semiconductor storage device of the second embodiment may further suppress variations in the memory characteristics as compared with the first embodiment.

### Third Embodiment

(Structure of Semiconductor Storage Device in Third Embodiment)

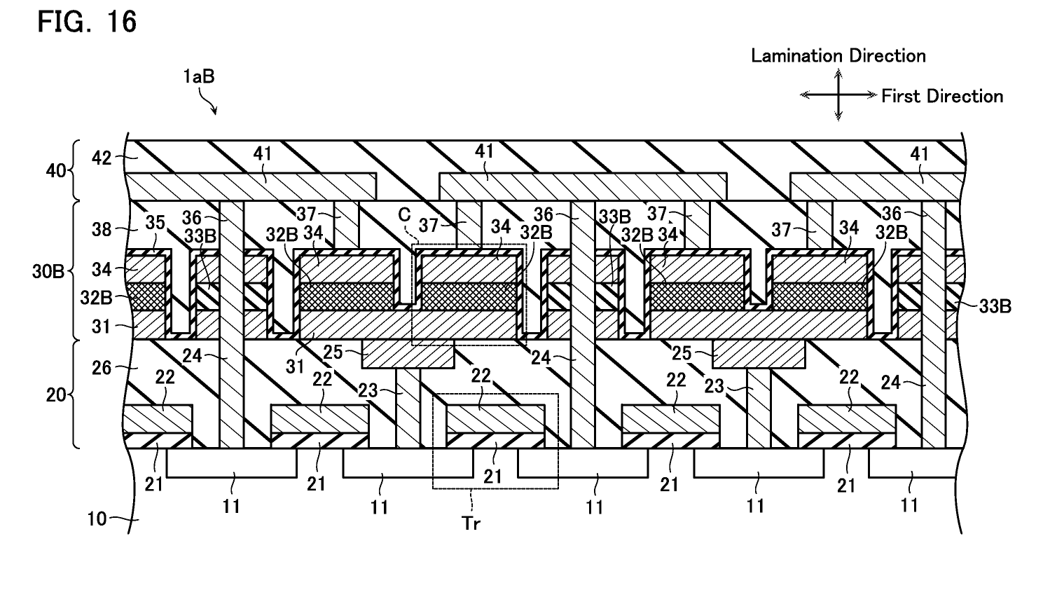

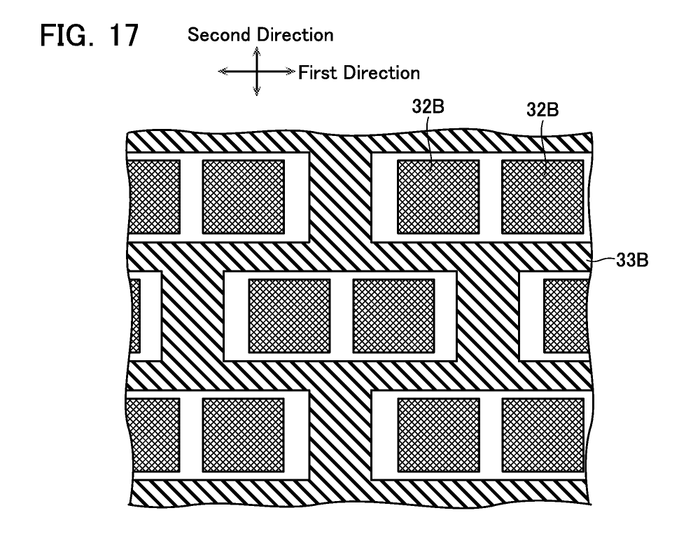

Referring now to FIGS. 16 and 17, a structure of a semiconductor storage device according to a third embodiment will be described below. FIG. 16 is a cross-sectional view of a memory cell array 1aB according to the third embodiment. FIG. 17 is a top plan view illustrating ferroelectric layers 32B and stopper layers 33B according to the third embodiment. Note that the same reference numerals represent the same components as the first and second embodiments, and description thereof will be omitted in the third embodiment.

As illustrated in FIGS. 16 and 17, the memory cell array 1aB according to the third embodiment has a capacitor layer 30B different from the first and second embodiments. The capacitor layer 30B has ferroelectric layers 32B and stopper layers 33B that are different from the first and second embodiments.

As illustrated in FIG. 17, the ferroelectric layers 32B are arranged in a staggered pattern in a plane provided in the first direction and a second direction (which is orthogonal to the lamination direction and the first direction). As illustrated in FIGS. 16 and 17, the stopper layers 33B are not formed on the side surfaces of the ferroelectric layers 32B. That is, the ferroelectric layers 32B are formed to be spaced apart from the stopper layers 33B. The stopper layers 33B are formed in a hound's tooth pattern, as viewed from above, so as to surround a pair of ferroelectric layers 32B at a certain interval.

(Advantages of Third Embodiment)

Advantages of the semiconductor storage device according to the third embodiment will be described below. As in the first and second embodiments, the stopper layers 33B are formed in the same layer as the ferroelectric layers 32B. Accordingly, the semiconductor storage device of the third embodiment has the same advantages as the first and second embodiments.

### Other Embodiments

While embodiments of the present invention have been described, the present invention is not intended to be limited to the disclosed embodiments, and various other changes, additions or the like may be made thereto without departing from the spirit of the invention.

For example, according to the first embodiment, the memory cell array 1a has the stopper layers 33. However, in the step of FIG. 10, the stopper layers 33 (the layers 33a) may be removed completely to form the memory cell array 1a.

In addition, while the semiconductor storage device according to the first and second embodiments mentioned above has been described as TC parallel unit serial connection type FeRAM, it may also be utilized in 1T type (transistor type), 1T1C type (capacitor type), or 2T2C type FeRAM applications.

What is claimed is:

1. A semiconductor storage device comprising:
a memory cell having a ferroelectric capacitor and a cell transistor connected in parallel, the memory cell comprising:
a first conductive layer above a substrate;
a ferroelectric layer on a top surface of the first conductive layer;
a second conductive layer on a top surface of the ferroelectric layer; and
a stopper layer in the same layer as the ferroelectric layer,
wherein a selection ratio of the stopper layer under chemical mechanical polishing (CMP) is higher than a selection ratio of the ferroelectric layer under CMP.

2. The semiconductor storage device of claim 1, wherein
the ferroelectric layer is in contact with a side surface of the stopper layer.

3. The semiconductor storage device of claim 2, wherein
the stopper layer comprises a side surface facing the ferroelectric layer, the side surface being inclined with respect to the substrate.

4. The semiconductor storage device of claim 2, wherein
the ferroelectric layer is apart from the stopper layer.

5. The semiconductor storage device of claim 4, wherein
the ferroelectric layer is in a staggered pattern in a plane parallel to the substrate.

6. The semiconductor storage device of claim 5, wherein
the stopper layer is in a hound's tooth check pattern in a plane parallel to the substrate around the ferroelectric layer.

7. The semiconductor storage device of claim 1, wherein
the memory cell further comprises:
a protection layer configured to cover a side surface of the first conductive layer and side and top surfaces of the second conductive layer.

8. The semiconductor storage device of claim 1, wherein
the memory cell further comprises:
source/drain layers on a surface of the substrate at a predetermined pitch;
a gate insulation layer across the source/drain layers on a top surface of the substrate; and
a gate conductive layer on a top surface of the gate insulation layer.

9. The semiconductor storage device of claim 1, wherein
the ferroelectric layer comprises at least one of lead zirconate titanate, strontium bismuth tantalite, and bismuth ferrite.

10. The semiconductor storage device of claim 1, wherein
the stopper layer comprises either alumina or silicon nitride, or lamination of alumina and a noble metal film.

11. The semiconductor storage device of claim 1, wherein
the first conductive layer and the second conductive layer comprises at least one of platinum (Pt), iridium (Ir), iridium dioxide (IrO₂), strontium oxide (SrO), ruthenium (Ru), and ruthenium oxide (RuO₂).

12. A method of manufacturing a semiconductor storage device, the method comprising:
depositing a first conductive layer above a substrate; depositing a stopper layer in a predetermined pattern on a top surface of the first conductive layer;
depositing a ferroelectric layer configured to cover the first conductive layer and the stopper layer;
planarizing the ferroelectric layer by CMP so that a top surface of the ferroelectric layer is aligned with a top surface of the stopper layer; and
depositing a second conductive layer on the respective top surfaces of the stopper layer and the planarized ferroelectric layer,
wherein a selection ratio of the stopper layer under CMP is higher than a selection ratio of the ferroelectric layer under CMP.

13. The method of manufacturing the semiconductor storage device of claim 12, further comprising
forming the stopper layer comprising a side surface inclined with respect to the substrate, while patterning the stopper layer.

14. The method of manufacturing the semiconductor storage device of claim 12, further comprising
forming the ferroelectric layer by growing the ferroelectric layer from the top and side surfaces of the stopper layer at a growing rate slower than a growing rate of the ferroelectric layer from the top surface of the first conductive layer.

15. The method of manufacturing the semiconductor storage device of claim 14, wherein
the first conductive layer comprises a heat conductivity higher than a heat conductivity of the stopper layer.

16. The method of manufacturing the semiconductor storage device of claim 14, wherein
the first conductive layer comprises a nucleation density higher than a nucleation density of the stopper layer.

17. The method of manufacturing the semiconductor storage device of claim 12, further comprising
forming the ferroelectric layer by Metal Organic Chemical Vapor Deposition.

18. The method of manufacturing the semiconductor storage device of claim 12, wherein
the ferroelectric layer comprises at least one of lead zirconate titanate, strontium bismuth tantalate, and bismuth ferrite.

19. The method of manufacturing the semiconductor storage device of claim 12, wherein
the stopper layer comprises either alumina or silicon nitride, or lamination of alumina and a noble metal film.

20. The method of manufacturing the semiconductor storage device of claim 12, wherein
the first conductive layer and the second conductive layer comprises at least one of Pt, Ir, IrO₂, SrO, Ru, and RuO₂.
